(19) United States
(12) Patent Application Publication
(10) Pub. No.: US 2021/0025052 A1
(43) Pub. Date: Jan. 28, 2021

(54) TINTED METAL PLATED PARTS AND METHODS OF MANUFACTURING TINTED METAL PARTS

(71) Applicant: Ford Global Technologies, LLC, Dearborn, MI (US)

(72) Inventors: Paul Kenneth Dellock, Northville, MI (US); Richard Gall, Ann Arbor, MI (US); Stuart C. Salter, White Lake, MI (US); David Brian Glickman, Southfield, MI (US); Joseph Myszka, Livonia, MI (US)

(73) Assignee: Ford Global Technologies, LLC, Dearborn, MI (US)

(21) Appl. No.: 16/518,340

(22) Filed: Jul. 22, 2019

(51) Int. Cl. C23C 16/06; C23C 28/00; C23C 16/50

(52) U.S. Cl. CPC C23C 16/06; B05D 5/068; C23C 16/50; C23C 28/322

(57) ABSTRACT

A method of manufacturing a tinted metal plated substrate includes injection molding a tinted polymer layer onto an activated metal layer of a metal plated substrate. The tinted polymer layer is a tinted polyurethane layer or a tinted polyurea layer and the activated metal layer can be a plasma activated metal layer, for example, an oxygen plasma activated metal layer that is free of a coupling agent when the tinted polymer layer is injected molded thereon. At least one additional metallic layer can be disposed between the activated metal layer and a polymer substrate. For example, at least one of a nickel layer and a copper layer can be disposed between an activated chromium layer and a polymer substrate.

### FIELD

The present disclosure relates to metal plated parts and particularly to tinted metal plated parts.

### BACKGROUND

The statements in this section merely provide background information related to the present disclosure and may not constitute prior art.

Components with an outer chromium containing layer provide a shiny, and sometimes mirror, surface that is aesthetically pleasing to consumers. Such components include chrome plated exterior and interior trim parts for a vehicle such as a chrome plated grille, a chrome plated console part, among others. Tinted chrome plated parts, i.e., chrome plated parts with a “tinted” color, are known, but the cost to manufacture such parts can be two to three times the cost of the chrome plated part itself.

The present disclosure addresses the issues of tinted chrome plated parts other issues related to manufacturing tinted chrome plated parts.

### SUMMARY

This section provides a general summary of the disclosure and is not a comprehensive disclosure of its full scope or all of its features.

In one form of the present disclosure, a method of manufacturing a tinted metal plated substrate includes injection molding a tinted polymer layer onto an activated metal layer (e.g., an activated chromium layer) of a metal plated substrate (e.g., a chrome plated substrate). In some aspects the tinted polymer layer is a tinted polyurethane layer or a tinted polyurea layer and the activated metal layer is a plasma activated metal layer. In such aspects the activated metal layer is an oxygen plasma activated metal layer that is free of a coupling agent when the tinted polymer layer is injected molded thereon.

The method includes injection molding the tinted polymer layer onto a metal plated metallic substrate, or in the alternative, injection molding the tinted polymer layer onto a metal plated polymer substrate. Non-limiting examples of metal plated polymer substrates include a chromium plated thermoplastic polymer substrate, a chromium plated acrylonitrile butadiene styrene substrate, a chromium plated polycarbonate+acrylonitrile butadiene styrene substrate, and a chromium plated nylon substrate, among others.

In some aspects of the present disclosure, the metal plated substrate includes at least one additional metallic layer between the activated metal layer and a polymer substrate. For example, at least one of a nickel layer and a copper layer is disposed between an activated chromium layer and a polymer substrate.

The method can further include injection molding a polymer substrate, forming a metal layer across at least a portion of the polymer substrate and plasma activating the metal layer to form the metal plated substrate with the activated metal layer. Also, a nickel layer is formed onto the injection molded polymer substrate and a copper layer is formed on the nickel layer before forming the metal layer. In some aspects the tinted polymer layer is injected molded onto the activated metal layer of the metal plated substrate using the same injection molding machine used to injection mold the polymer substrate.

In another form of the present disclosure, a method of manufacturing a tinted chrome plated substrate includes injection molding a substrate, forming a chromium layer across at least a portion of the substrate, activating the chromium layer; and injection molding a tinted polymer layer onto the activated chromium layer. In some aspects of the present disclosure, the substrate is a polymer substrate, the chromium layer is plasma activated and the plasma activated chromium layer is free of a coupling agent when the tinted polymer layer is injected molded onto the plasma activated chromium layer. Also, the tinted polymer layer can be a tinted polyurethane layer or a tinted polyurea layer.

In still another from of the present disclosure, a method of manufacturing a tinted chrome plated substrate includes injection molding a polymer substrate, forming a copper layer onto the polymer substrate, forming a nickel layer onto the copper layer, forming a chromium layer onto the copper layer, plasma activating the chromium layer, and injection molding a tinted polymer layer onto the activated chromium layer.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a perspective view of one form of a tinted metal plated substrate according to the teachings of the present disclosure;

FIG. 2 is a top view of the tinted metal plated substrate in FIG. 1;

FIG. 3 is a perspective view of another form of a tinted metal plated substrate according to the teachings of the present disclosure; and

FIGS. 4A-4E illustrate a plurality of steps for manufacturing a tinted metal plated substrate according to the teachings of the present disclosure with: FIG. 4A illustrating one step for manufacturing a tinted metal plated substrate; FIG. 4B illustrating another step for manufacturing the tinted metal plated substrate; FIG. 4C illustrating still another step for manufacturing the tinted metal plated substrate; FIG. 4D illustrating yet another step for manufacturing the tinted metal plated substrate; and FIG. 4E illustrating still yet another step for manufacturing the tinted metal plated substrate.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features. Examples are provided to fully convey the scope of the disclosure to those who are skilled in the art. Numerous specific details are set forth such as types of specific components, devices, and methods, to provide a thorough understanding of variations of the present disclosure. It will be apparent to those skilled in the art that specific details need not be employed and that the examples provided herein, may include alternative embodiments and are not intended to limit the scope of the disclosure. In some examples, well-known processes, well-known device structures, and well-known technologies are not described in detail.

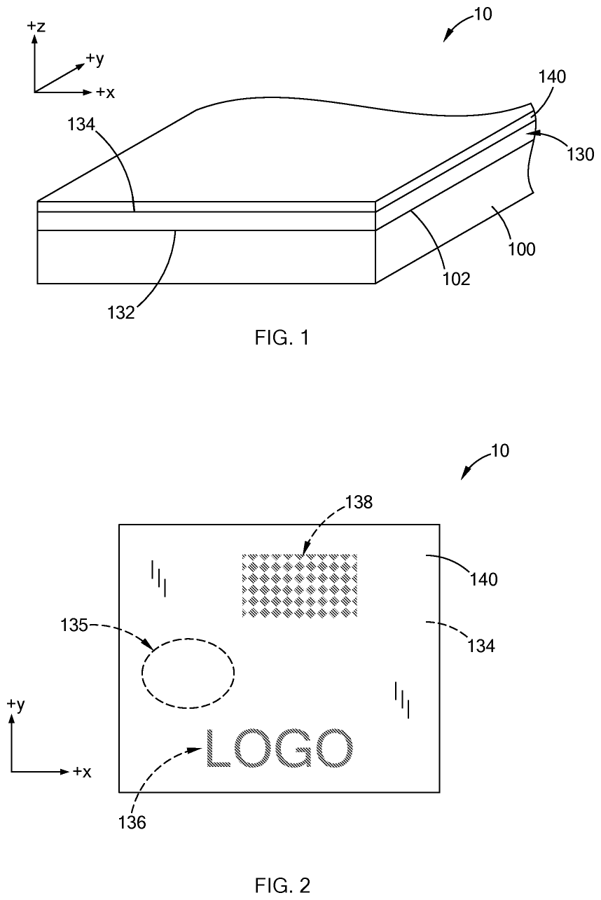

Referring now to FIG. 1, a metal plated substrate 10 (also referred to herein as a “metal plated part”) according to one form of the present disclosure includes a substrate 100, a metallic layer 130 (also referred to herein simply as a “metal layer”) disposed on the substrate 100 and an injection molded tinted layer 140 disposed on the metal layer 130. The substrate 100 includes an outer surface 102 (+z direction), and the metal layer 130 includes an inner surface 132 (−z direction) and an outer surface 134 (+z direction). In some aspects of the present disclosure the inner surface 132 of the metal layer 130 is disposed in contact with the outer surface 102 of the substrate 100 and the injection molded tinted layer 140 is disposed in contact with the outer surface 134 of the metal layer 130. In such aspects the outer surface 134 is free from a coupling agent, i.e., the injection molded tinted layer 140 is disposed in contact with the outer surface 134 without the use of a coupling agent such as silane coupling agents, chromium complexes, inorganic esters, zirconates, aluminates, and titanates, among others.

The substrate 100 can be any known or yet to be developed substrate including, but not limited to, a substrate for a metal plated vehicle grille, a substrate for a metal plated vehicle console part, a substrate for a metal plated appliance part, among others. Also, the substrate 100 can be formed from known or yet to be developed polymer materials, metallic materials, ceramic materials, and combinations thereof. Non-limiting examples of substrate materials include thermoplastic polymers such as acrylonitrile butadiene styrene (ABS), polycarbonate+acrylonitrile butadiene styrene (PC/ABS), nylon, among others.

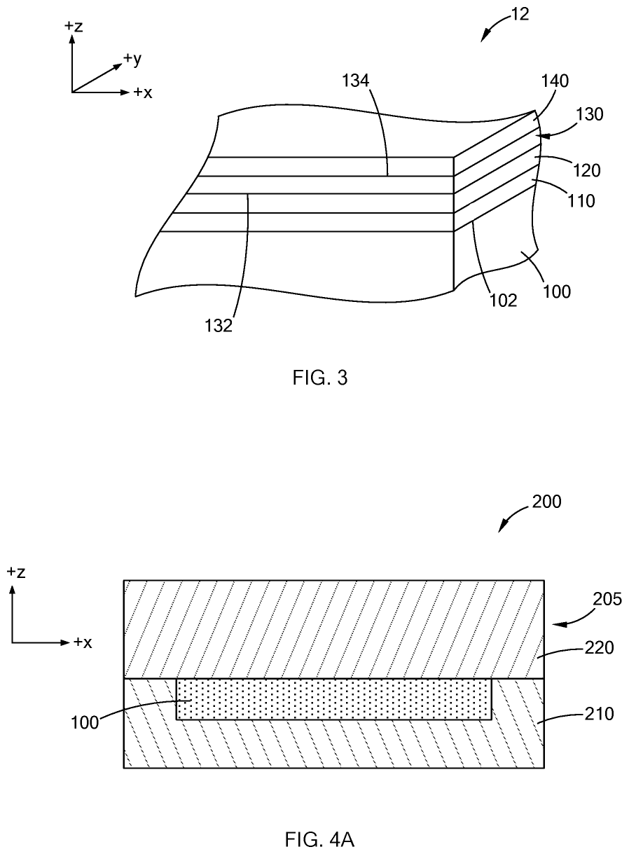

The outer surface 134 of the metal layer 130 can be smooth, i.e., does not have intentional indentations, roughness, logos, patterns, grain, and the like, and may have a mirror surface finish as depicted by region 135 in FIG. 2. In the alternative, or in addition to, the outer surface 134 has at least one intentional indentation, roughness, logo 136, pattern 138, grain, among others as shown in FIG. 2. The metal layer 130 can be any metal or combination of metals (i.e., an alloy) formed or deposited onto the substrate 100 using known or yet to be developed metal layer deposition techniques. Non-limiting examples of metals include chromium, nickel, copper, iron, tin, silver, gold and alloys thereof. Non-limiting examples of metal layer forming or deposition techniques include electrochemical deposition, electroless deposition, physical vapor deposition (PVD), chemical vapor deposition (CVD), among others.

The injection molded layer 140 can be formed from known or yet to be developed polymeric materials. Non-limiting examples of polymers used to form the injection molded tinted layer 140 include polyurethane (e.g., thermoplastic polyurethane) and polyurea, among others. The injection molded tinted layer 140 can be a dear coat layer, for example, a tinted clear coat layer that is transparent such that the outer surface 134 of the metal layer 130 is visible through the injection molded tinted layer 140 to an observer viewing the tinted metal plated part 10. It should be understood that a tinted injection molded tinted layer 140 provides a “color” (e.g., pink, blue, red, among others) and an aesthetically pleasing appearance or visual effect to a metal plated part 10 being viewed by an individual while still allowing the underlying metal layer 130, with or without a logo 126, pattern 138, and the like, to be seen by the individual. It should also be understood that a non-tinted clear coat layer (i.e., an injection molded layer 140 without color) can be injection molded onto the metal layer 130 to provide a chromium (silvery metallic) appearance, and such a metal plated part is included within the teachings of the present disclosure.

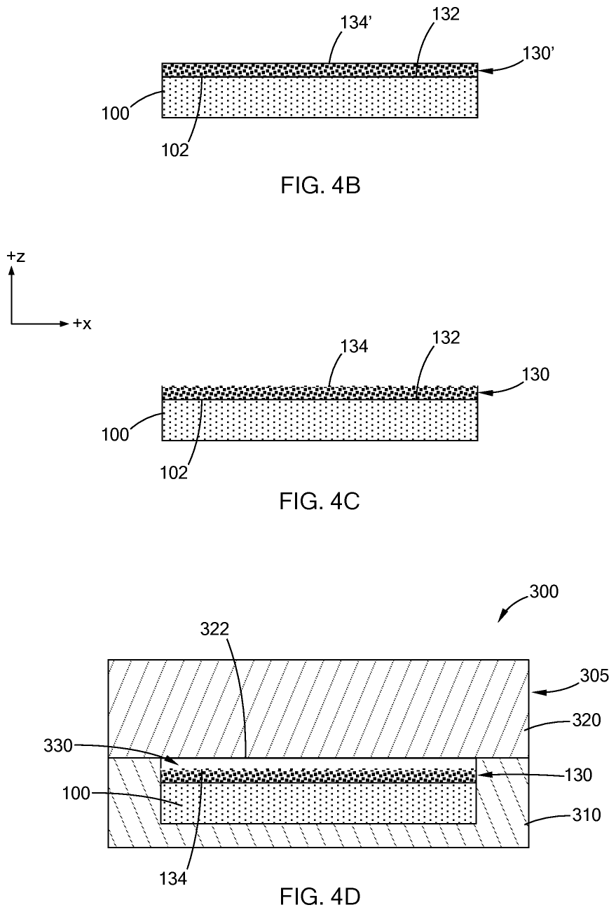

Referring now to FIG. 3, a metal plated substrate 12 according to another form of the present disclosure includes the substrate 100, the metal layer 130 and the injection molded tinted layer 140. However at least one additional layer is disposed between the outer surface 102 of the substrate 100 and the inner surface 132 of the metal layer 130. In some aspects a copper containing layer 110 (also referred to herein simply as a “copper layer”) is disposed between the substrate 100 and the metal layer 130. In other aspects a nickel containing layer 120 (also referred to herein simply as a “nickel layer”) is disposed between the substrate 100 and the metal layer 130. In still other aspects a copper layer 110 is disposed between the substrate 100 and the metal layer 130, and a nickel layer 120 is disposed between the copper layer 110 and the metal layer 130. Similar to the metal plated substrate 10 shown in FIG. 1 in some aspects the injection molded layer 140 is disposed in contact with the outer surface 134 of the metal layer 130. In such aspects the outer surface 134 is free from a coupling agent, i.e., the injection molded layer 140 is disposed in contact with the outer surface 134 without the use of a coupling agent.

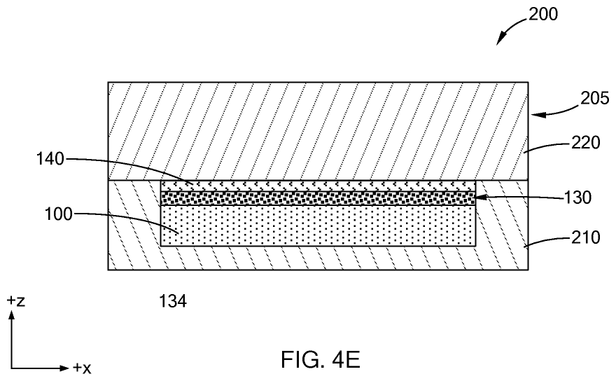

Referring now to FIGS. 4A-4E, FIG. 4A illustrates forming the substrate 100 in an injection molding machine 200. The injection molding machine 200 includes a mold 205 with a first die 210 and a second die 220. A substrate material is injected into a cavity or space (not labeled) between the first die 210 and the second die 220 to form the substrate 100. After the substrate 100 is formed, it is removed from the mold 205 and a precursor metal layer 130′ is formed on at least one surface 102 of the substrate 100 as shown in FIG. 4B. As used herein, the phrase “precursor metal layer” refers to a metal layer prior to being activated as described herein. As noted above, one or more layers, for example a copper layer 110 and/or a nickel layer 120, can be disposed between the substrate 100 and the precursor metal layer 130′.

Referring now to FIG. 4C, the precursor metal layer 130′, i.e., the outer surface 134 of the precursor metal layer 130′, is activated to provide the metal layer 130 (also referred to herein as an “activated metal layer”) on the substrate 100. In some aspects the precursor metal layer 130′ is activated by a plasma treatment. For example, at least the precursor metal layer 130′ is positioned within a plasma chamber, a process gas (e.g., a gas with oxygen, nitrogen and/or air) is introduced into the plasma chamber, and electrical energy is applied such that a plasma is formed within the plasma chamber. It should be understood that the plasma in the plasma chamber (i.e., the plasma treatment) reduces, removes and/or eliminates contaminants such as oils, grease, among others from an outer surface of the metal layer 130. That is, the plasma treatment provides a pristine surface suitable for bonding without producing harmful waste material. Also, oxygen atoms within the plasma bond with the outer surface of the precursor metal layer 130′ and creates active surface sites that enhance bonding of the outer surface 134 of the metal layer 130 with the injected molded layer 140. It should be understood that the combination of the plasma treatment of the precursor metal layer 130′ and the injection molding of the tinted layer onto the metal layer 130 reduces or removes the need for a coupling agent to produce the metal plated substrate 10 or 12. It should also be understood that other surface treatments such as flame treatment, among others, can be sued to activate the precursor metal layer 130′.

Referring now to FIG. 4D, in one form of the present disclosure the substrate 100 with the metal layer 130 is positioned or placed back into another injection molding machine 300 with a mold 305 comprising a first mold 310 and a second mold 320. A small gap or space 330 is provided between the outer surface 134 of the metal layer 130 and a surface 322 of the second die 320. In another from of the present disclosure, the substrate 100 with the metal layer 130 is placed back into in the mold 205 of the injection molding machine 200 (FIG. 4A) and the first die 210 and the second die 220 positioned such that the space 230 (e.g., 0.5 mm) is present between the activated metal layer 130 and a surface (not labeled) of the second die 220. In either form, tinted polyurethane or tinted polyurea, among others, is injected molded into the space 330 to form the injection molded tinted layer 140 on the metal layer 130 as shown in FIG. 4E, thereby providing a tinted metal plated substrate 10 (FIG. 1). It should be understood, and as noted above, the activated metal layer 130 enhances bonding with the injection molded tinted layer 140 such that a resilient, self-healing surface that is resistant to chipping when impact by stones or rocks is provided.

It should be understood from the teachings of the present disclosure that a metal plated part with an injection molded tinted layer and a method for manufacturing the metal plated part with the injection molded tinted layer is provided. The metal plated part combines the appearance of an underlying metal layer with a tinted (transparent) outer to provide a pleasing and possibly unique visual appearance to consumers and enhance consumer satisfaction with machines (e.g., vehicles and appliances), artwork, furniture, tools, among others, with the metal plated part.

Although the terms first, second, third, etc. may be used to describe various elements, components, regions, layers and/or sections, these elements, components, regions, layers and/or sections, should not be limited by these terms. These terms may be only used to distinguish one element, component, region, layer and/or section, from another element, component, region, layer and/or section. Terms such as “first,” “second,” and other numerical terms when used herein do not imply a sequence or order unless clearly indicated by the context. Thus, a first element, component, region, layer or section, could be termed a second element, component, region, layer or section without departing from the teachings of the example forms. Furthermore, an element, component, region, layer or section may be termed a “second” element, component, region, layer or section, without the need for an element, component, region, layer or section termed a “first” element, component, region, layer or section.

Specially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above or below. The device may be otherwise oriented (rotated 90 degrees or at other orientations) and the spatially relative descriptors used herein interpreted accordingly.

As used herein, the phrase at least one of A, B, and C should be construed to mean a logical (A OR B OR C), using a non-exclusive logical OR, and should not be construed to mean “at least one of A, at least one of B, and at least one of C.

Unless otherwise expressly indicated, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, manufacturing technology, and testing capability.

The terminology used herein is for the purpose of describing particular example forms only and is not intended to be limiting. The singular forms “a,” “an,” and “the” may be intended to include the plural forms as well, unless the context clearly indicates otherwise. The terms “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

The description of the disclosure is merely exemplary in nature and, thus, examples that do not depart from the substance of the disclosure are intended to be within the scope of the disclosure. Such examples are not to be regarded as a departure from the spirit and scope of the disclosure. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A method of manufacturing a tinted metal plated substrate comprising injection molding a tinted polymer layer onto an activated metal layer of a metal plated substrate.

2. The method according to claim 1, wherein the polymer layer is a tinted polyurethane layer or a tinted polyurea layer.

3. The method according to claim 1, wherein the activated metal layer is a plasma activated chromium layer.

4. The method according to claim 1, wherein the activated metal layer is an oxygen plasma activated chromium layer.

5. The method according to claim 1, wherein the activated metal layer is free of a coupling agent when the polymer layer is injected molded thereon.

6. The method according to claim 1, wherein the metal plated substrate is a chrome plated metallic substrate.

7. The method according to claim 1, wherein the metal plated substrate is a chrome plated polymer substrate.

8. The method according to claim 7, wherein the metal plated polymer substrate is a chrome plated thermoplastic polymer substrate.

9. The method according to claim 7, wherein the metal plated polymer substrate is a chrome plated acrylonitrile butadiene styrene substrate.

10. The method according to claim 7, wherein the metal plated polymer substrate is a chrome plated polycarbonate+acrylonitrile butadiene styrene substrate.

11. The method according to claim 7, wherein the metal plated polymer substrate is a chrome plated nylon substrate.

12. The method according to claim 1, wherein the metal plated substrate comprises a chrome plated substrate with an activated chromium layer and at least one additional metallic layer between the activated chromium layer and a polymer substrate.

13. The method according to claim 12, wherein the at least one metallic layer comprises a nickel layer and a copper layer.

14. The method according to claim 1 further comprising injection molding a polymer substrate, forming a chromium layer across at least a portion of the polymer substrate and plasma activating the chromium layer to form a chrome plated substrate with an activated chromium layer.

15. The method according to claim 14 further comprising forming a nickel layer onto the injection molded polymer substrate and forming a copper layer onto the nickel layer before forming the chromium layer.

16. The method according to claim 15, wherein the tinted polymer layer is injected molded onto the activated chromium layer of the metal plated substrate using the same injection molding machine used to injection mold the polymer substrate.

17. A method of manufacturing a tinted chrome plated substrate comprising:
injection molding a substrate;
forming a chromium layer across at least a portion of the substrate;
activating the chromium layer; and
injection molding a tinted polymer layer onto the activated chromium layer.

18. The method according to claim 17, wherein the substrate is a polymer substrate, the chromium layer is plasma activated and the plasma activated chromium layer is free of a coupling agent when the tinted polymer layer is injected molded onto the plasma activated chromium layer.

19. The method according to claim 17, wherein the substrate is a polymer substrate, the chromium layer is plasma activated and the tinted polymer layer is a tinted polyurethane layer or a tinted polyurea layer.

20. A method of manufacturing a tinted chrome plated substrate comprising:
injection molding a polymer substrate;
forming a copper layer onto the polymer substrate;
forming a nickel layer onto the copper layer;
forming a chromium layer onto the copper layer;
plasma activating the chromium layer; and
injection molding a tinted polymer layer onto the activated chromium layer.
